(19) United States
(12) Patent Application Publication
(10) Pub. No.: US 2022/0415701 A1
(43) Pub. Date: Dec. 29, 2022

(54) SUBSTRATE LIFT MECHANISM AND SUBSTRATE PROCESSING APPARATUS INCLUDING SAME

(71) Applicant: ASM IP Holding B.V., Almere (NL)

(72) Inventor: Kazuhiro Nishiwaki, Tokyo (JP)

(21) Appl. No.: 17/847,470

(22) Filed: Jun. 23, 2022

Related U.S. Application Data
(60) Provisional application No. 63/215,979, filed on Jun. 28, 2021.

(51) Int. Cl. H01L 21/687; B25J 11/00; B25J 15/00; H01J 37/32

(52) U.S. Cl. CPC H01L 21/68742; B25J 11/0095; B25J 15/0014; H01J 37/3244; H01L 21/68792; H01J 37/32082; H01J 37/32724; H01L 21/68785

(57) ABSTRACT

A substrate processing apparatus is disclosed. An exemplary substrate processing apparatus includes a reaction chamber; a susceptor plate positioned within the reaction chamber, constructed and arranged to support a substrate, and provided with one or more holes; a substrate lift mechanism comprising: a plurality of lift pins to support the substrate; and a lift pin support member to move the lift pins; in a vertical direction through the one or more holes; a substrate transfer robot provided with one or more robotic arms to transfer the substrate to a position above the lift pins; and a gas supply unit constructed and arranged to face the susceptor plate; wherein the gas supply unit is constructed and arranged to move in the vertical direction thereby positioning the gas supply unit in a processing position in the reaction chamber.

### CROSS-REFERENCE TO RELATED APPLICATIONS

This application claims priority to U.S. Provisional Patent Application Ser. No. 63/215,979 filed Jun. 28, 2021 titled SUBSTRATE LIFT MECHANISM AND SUBSTRATE PROCESSING APPARATUS INCLUDING SAME, the disclosure of which is hereby incorporated by reference in its entirety.

### FIELD OF INVENTION

The present disclosure relates generally to a substrate processing apparatus. More particularly, exemplary embodiments of the present disclosure relate to a substrate lift mechanism suitable for use therein.

### BACKGROUND OF THE DISCLOSURE

FIG. 1 is a schematic view of a substrate processing apparatus. During a substrate transfer process, a substrate transfer robot 30 and lift pins 40 are used to facilitate placement and removal of a substrate 1 on and from a susceptor 20. In such cases, the lift pin 40 is positioned above the surface of the susceptor 20 by lowering the susceptor 20 to be within the substrate transfer region of a reaction chamber 10. The substrate 1 is transferred from the substrate transfer robot 30 to the lift pins 40. Then, the susceptor 20 is raised such that the substrate 1 rests on the susceptor 20.

The susceptor 20 and the substrate 1 are then raised to a processing position. After processing on the substrate 1, the susceptor 20 is lowered, and the substrate 1 is then removed from the susceptor 20 using the substrate transfer robot 30 and the lift pins 40.

FIG. 2 is a schematic view of a substrate processing apparatus including mechanisms to move the susceptor 20 and the substrate transfer robot 30. Although such wafer transferring techniques work relatively well to place the substrate 1 within and remove the substrate 1 from the reaction chamber 10, a mechanism 70 to move the susceptor 20 and a mechanism 60 to move the substrate transfer robot 30 are relatively complex and require a large space below the reaction chamber 10. Recently, there has been a demand to have new functions for the susceptor 20 such as multi-zone heater, electrostatic chuck, RF noise filter, and cables 80 and safety measures for these parts, which require more space below the reaction chamber 10. Accordingly, improved mechanisms and techniques for transferring and processing the substrate are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. The substrate processing apparatus comprises a reaction chamber; a susceptor plate positioned within the reaction chamber, constructed and arranged to support a substrate, and provided with one or more holes; a substrate lift mechanism comprising: a plurality of lift pins to support the substrate; and a lift pin support member to move the lift pins in a vertical direction through the one or more holes; a substrate transfer robot provided with one or more robotic arms to transfer the substrate to a position above the lift pins; and a gas supply unit constructed and arranged to face the susceptor plate; wherein the gas supply unit is constructed and arranged to move in the vertical direction thereby positioning the gas supply unit in a processing position in the reaction chamber.

In various embodiments, the substrate processing apparatus may further include a susceptor shaft supporting the susceptor plate, wherein a lower end of the susceptor shaft may be connected to the reaction chamber.

In various embodiments, the substrate lifting mechanism may further include a first lift shaft coupled to the lift pin support member; a first shaft support member coupled to the first lift shaft; a first bracket coupled to the first shaft support member; a first ball screw rotatably coupled to the first bracket; and a first motor coupled to the first ball screw and configured to rotate the first ball screw thereby moving the substrate in the vertical direction.

In various embodiments, the gas supply unit may further include a shower plate provided with a plurality of gas channels; an upper body coupled to the shower plate; a second lift shaft coupled to the upper body; a second shaft support member coupled to the second lift shaft; a second bracket coupled to the second shaft support member; a second ball screw rotatably coupled to the second bracket; and a second motor coupled to the second ball screw and configured to rotate the second ball screw thereby moving the shower plate in the vertical direction.

In various embodiments, the substrate processing apparatus may further include a plurality of magnetic elements, one of which is provided to a lower end of each lift pin, and the other of which is provided to a surface of the lift pin support member.

In various embodiments, the shower plate and susceptor plate may serve as electrodes.

In various embodiments, the substrate processing apparatus may further include an RF generator electrically coupled in RF power providing communication to the shower plate, with the susceptor plate electrically grounded.

In various embodiments, the substrate processing apparatus may further include a first rod disposed between the RF generator and the shower plate and a second rod disposed between the susceptor plate and ground.

In various embodiments, the susceptor assembly may be provided with a heater.

In various embodiments, the substrate processing apparatus may further include a third rod embedded within the susceptor shaft, the third rod being connected to the heater.

In various embodiments, the third rod may be power cable.

In various embodiments, the third rod may be provided with a plurality of cables, each of which is connected to a zone of the heater.

In various embodiments, the third rod may be a thermocouple cable.

In various embodiments, each of the second rod and the third rod may be provided with a lower connector at the lower end.

In various embodiments, the substrate processing apparatus may further include upper connectors embedded in a bottom wall of the reaction chamber, wherein each of the upper connectors is configured to connect the lower connector.

In various embodiments, the substrate processing apparatus may further include one or more reaction chambers, each reaction chamber comprising two or more stations, each station comprising an upper compartment and a lower compartment, wherein the upper compartment is configured to contain a substrate during processing of the substrate, and wherein the lower compartment comprises a shared intermediate space between the two or more stations; two or more susceptor assemblies, each of which are provided with a susceptor plate, being positioned in each station; wherein the susceptor plate is constructed and arranged to support the substrate and provided with one or more holes formed therethrough; wherein two or more substrate lift mechanisms are provided, each comprising: a plurality of lift pins to support the substrate each station; and a lift pin support member to engage with the lift pins; wherein the substrate lift mechanism is configured to move in a vertical direction through the one or more holes; a substrate transfer robot centrally disposed relative to the stations and provided with one or more robotic arms to transfer the substrate above the lift pins in the shared intermediate space; and two or more gas supply units, each of which is constructed and arranged to face the susceptor plate; wherein the gas supply unit is configured to move in the vertical direction thereby positioning the substrate in a processing position of the upper compartment.

In various embodiments, the susceptor assemblies may further include a susceptor shaft supporting the susceptor plate, wherein a lower end of the susceptor shaft is connected to the reaction chamber.

In various embodiments, the substrate transfer robot may be configured to horizontally move the substrate from one of the stations to the other one of the stations.

In various embodiments, the substrate transfer robot may further include a shaft coupled to the robotic arms; a motor rotatably coupled to the shaft to provide rotary movement to the robotic arms around an axis of the shaft.

In various embodiments, each of the gas supply unit may further include a shower plate provided with a plurality of gas channels; an upper body coupled to the shower plate; and a lift shaft coupled to the upper body.

In various embodiments, the substrate processing apparatus may further include a common shaft support member coupled to the lift shafts; a bracket coupled to the common shaft support member; a ball screw rotatably coupled to the bracket; and a motor coupled to the ball screw and configured to rotate the ball screw thereby moving the shower plate in the vertical direction.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a schematic diagram of a substrate processing apparatus.

FIG. 2 is a schematic diagram of a substrate processing apparatus including mechanisms to move the susceptor and the substrate transfer robot.

FIG. 3 is a schematic diagram of a substrate processing apparatus in an embodiment of the present invention.

FIG. 4 is a schematic diagram of a substrate processing apparatus including mechanisms for lift pins and a gas supply unit in an embodiment of the present invention.

FIG. 5A is a schematic diagram of a substrate processing apparatus in an embodiment of the present invention.

FIG. 5B is an enlarged view of susceptor shaft and rods in an embodiment of the present invention.

FIG. 6 is a schematic diagram of a substrate processing apparatus including 4 process stations in an embodiment of the present invention.

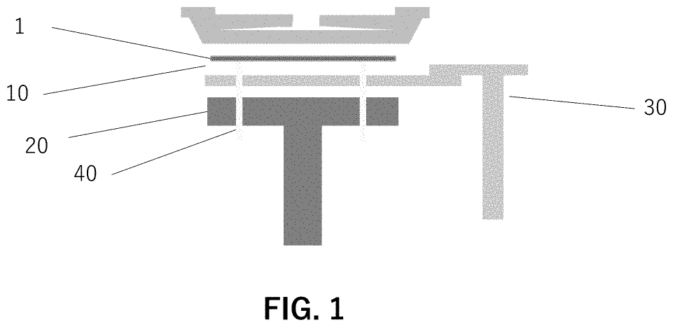

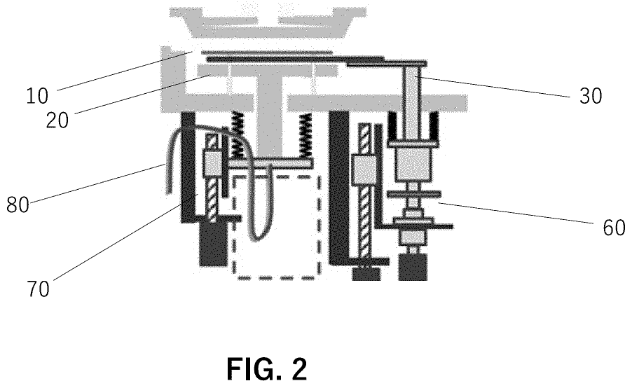

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

In this disclosure, “gas” may include material that is a gas at normal temperature and pressure, a vaporized solid and/or a vaporized liquid, and may be constituted by a single gas or a mixture of gases, depending on the context. A gas other than the process gas, i.e., a gas introduced without passing through a gas supply unit, such as a shower plate, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied. The terms precursor and reactant can be used interchangeably.

As used herein, the term “substrate” may refer to any underlying material or materials that may be used, or upon which, a device, a circuit, or a film may be formed.

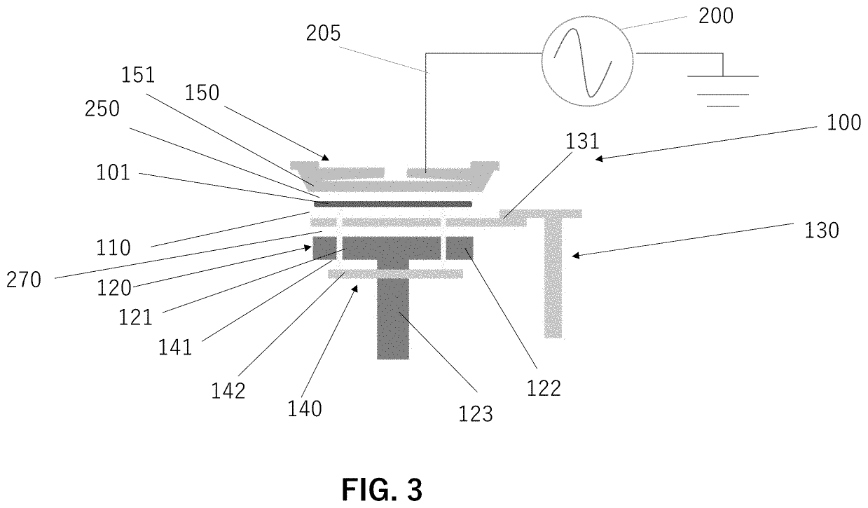

FIG. 3 is a schematic diagram of a substrate processing apparatus 100 in an embodiment of the present invention. A substrate processing apparatus 100 comprises a reaction chamber 110; a susceptor plate 122 positioned within the reaction chamber 110, constructed and arranged to support a substrate 101, and provided with one or more holes 121. The substrate processing apparatus 100 further includes a substrate lift mechanism 140 having a plurality of lift pins 141 to support the substrate 101; and a lift pin support member 142 to move the lift pins 141 in a vertical direction through the one or more holes 121. Further, the substrate processing apparatus 100 includes a substrate transfer robot 130 provided with one or more robotic arms 131 to transfer the substrate 101 to a position above the lift pins 141; and a gas supply unit 150 constructed and arranged to face the susceptor plate 122. The gas supply unit 150 is constructed and arranged to move in the vertical direction thereby positioning the gas supply unit 150 in a processing position in the reaction chamber 110.

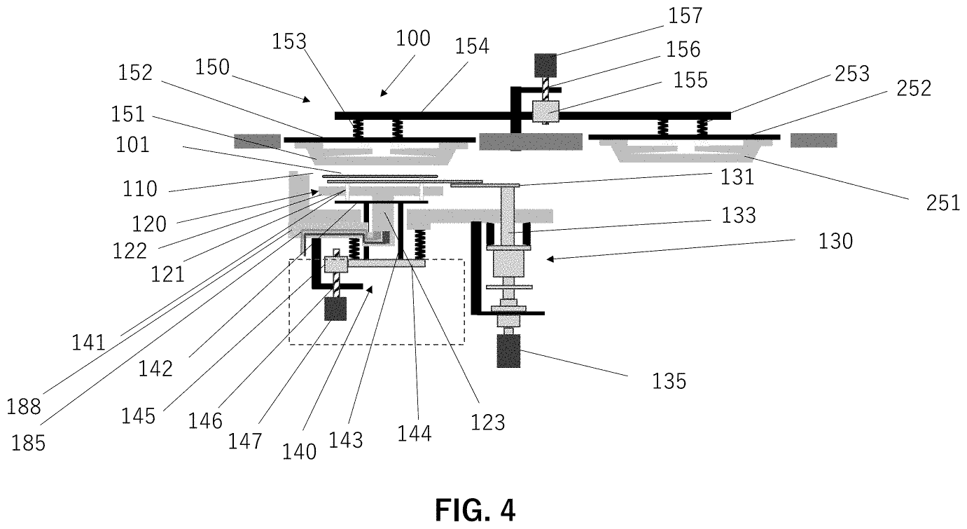

FIG. 4 is a schematic diagram of a substrate processing apparatus 100 including mechanisms for the lift pins 141 and the gas supply unit 150 in an embodiment of the present invention. The substrate processing apparatus 100 may further comprise a susceptor shaft 123 supporting the susceptor plate 122. A lower end of the susceptor shaft 123 may be connected to the reaction chamber 110 so as not to move.

The substrate lift mechanism 140 may further comprise a first lift shaft 143 coupled to the lift pin support member 142; a first shaft support member 144 coupled to the first lift shaft 143; a first bracket 145 coupled to the first shaft support member 144; a first ball screw 146 rotatably coupled to the first bracket 145; and a first motor 147 coupled to the first ball screw 146. The first motor 147 may be configured to rotate the first ball screw 146 thereby moving the substrate 101 in the vertical direction.

The gas supply unit 150 may further comprise a shower plate 151 provided with a plurality of gas channels; an upper body 152 coupled to the shower plate 151; a second lift shaft 153 coupled to the upper body 152; a second shaft support member 154 coupled to the second lift shaft 153; a second bracket 155 coupled to the second shaft support member 154; a second ball screw 156 rotatably coupled to the second bracket 155; and a second motor 157 coupled to the second ball screw 156. The second motor 157 may be configured to rotate the second ball screw 156 thereby moving the shower plate 151 in the vertical direction. A reactant gas may be supplied through a shared line whereas a precursor gas may be supplied through unshared lines.

The substrate processing apparatus 100 may further comprise a plurality of magnetic elements, one of which is provided to a lower end of each lift pin 141, and the other is provided to a surface of the lift pin support member 142.

The shower plate 151 and susceptor plate 122 may serve as electrodes. An RF generator 200 may be electrically coupled in RF power providing communication to the shower plate 151, with the susceptor plate 122 electrically grounded. By providing a pair of electrically conductive flat-plate electrodes 151, 122 in parallel and facing each other in the interior of a reaction chamber 110, applying HRF power (for example, 13.56 MHz or 27 MHz) to one side 151, and electrically grounding the other side 122, a plasma may be excited between the shower plate 151 and the susceptor plate 122.

As shown in FIG. 3, a first rod 205 may be disposed between the RF generator 200 and the shower plate 151.

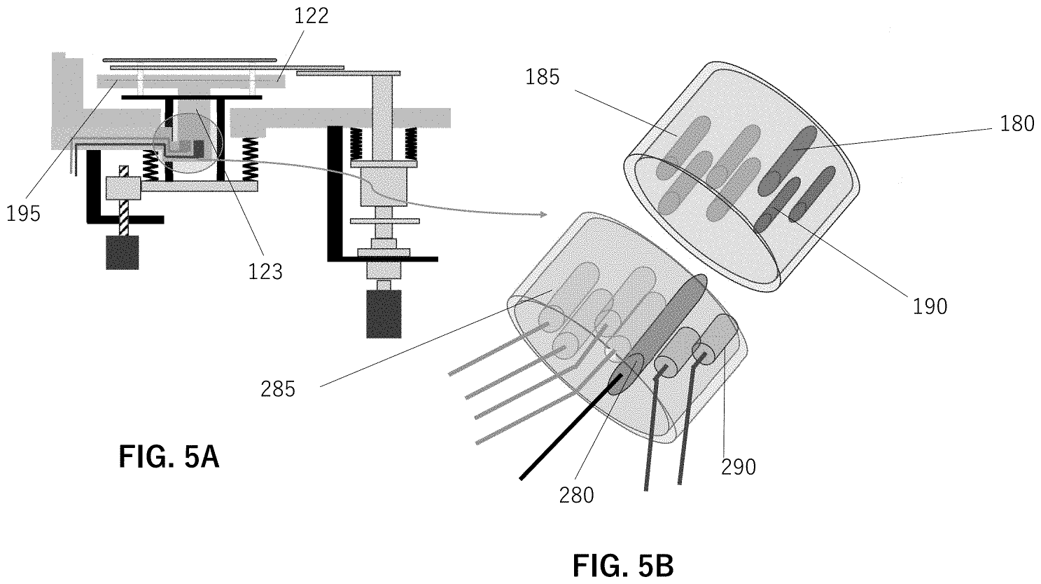

FIG. 5A is a schematic diagram of the substrate processing apparatus 100 in an embodiment of the present invention. FIG. 5B is an enlarged view of susceptor shaft 123 and rods in an embodiment of the present invention.

A second rod 180 may be disposed between the susceptor plate 122 and ground. The susceptor assembly 120 may be provided with a heater 195. A third rod 185, 190 may be embedded within the susceptor shaft 123. The third rod 185, 190 may be connected to the heater 195. The third rod 185 may be power cable. The third rod 185 may be provided with a plurality of cables, each of which is connected to a zone of the heater 195 for multi-zone heater so that temperature is controlled independently. The third rod 190 may be a thermocouple cable.

Each of the second rod 180 and the third rod 185, 190 may be provided with a lower connector at a lower end. Upper connectors 280, 285, 290 may be embedded in a bottom wall of the reaction chamber 110. Each of the upper connector may be configured to connect the lower connector. Since the lower end of the susceptor shaft 123 is connected to the reaction chamber 110 by the connectors, a mechanism to move the susceptor 20 is not required, resulting in more space below the reaction chamber 110.

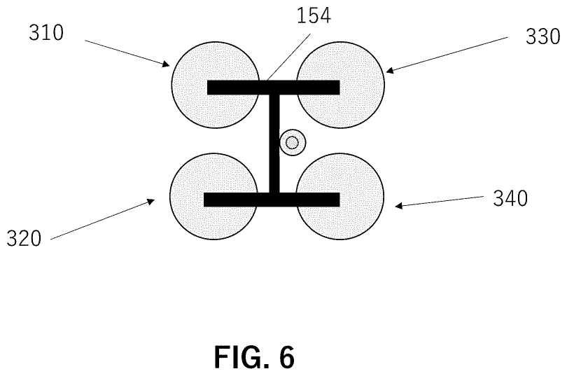

FIG. 6 is a schematic diagram of the substrate processing apparatus 100 including 4 process stations in an embodiment of the present invention. The substrate processing apparatus 100 may comprise one or more reaction chamber modules, each reaction chamber module comprising four stations 310, 320, 330, 340, each station comprising an upper compartment and a lower compartment, wherein the upper compartment is configured to contain a substrate 101 during processing of the substrate, and wherein the lower compartment comprises a shared intermediate space between the two or more stations.

The substrate transfer robot 130 may be centrally disposed relative to the stations 310, 320, 330, and 340 and provided with one or more robotic arms 131 to transfer the substrate 101 above the lift pins 141 in the shared intermediate space. The substrate transfer robot 130 may be configured to horizontally move the substrate 110 from one of the stations to the other one of the stations. Because the lift pin support member 142 moves the lift pins 141 in a vertical direction, it is not necessary that the substrate transfer robot 130 move in a vertical direction, thereby simplifying the mechanism of the substrate transfer robot 130.

The substrate processing apparatus 100 may further comprise a common shaft support member 154 coupled to the lift shafts 153, 253; a bracket 155 coupled to the common shaft support member 154; a ball screw 156 rotatably coupled to the bracket 155; and a motor 157 coupled to the ball screw 156.

A skilled artisan will appreciate that the apparatus includes one or more controller(s) programmed or otherwise configured to control the motor and cause the deposition and reactor cleaning processes to be conducted. The controller(s) may be communicated with the various power sources, heating systems, motors, pumps, robotics, and gas flow controllers or valves of the reactor, as will be appreciated by the skilled artisan.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus, comprising:
a reaction chamber;
a susceptor plate positioned within the reaction chamber, constructed and arranged to support a substrate, and provided with one or more holes;
a substrate lift mechanism comprising:
a plurality of lift pins to support the substrate; and
a lift pin support member to move the lift pins in a vertical direction through the one or more holes;
a substrate transfer robot provided with one or more robotic arms to transfer the substrate to a position above the lift pins; and
a gas supply unit constructed and arranged to face the susceptor plate;
wherein the gas supply unit is constructed and arranged to move in the vertical direction thereby positioning the gas supply unit in a processing position in the reaction chamber.

2. The substrate processing apparatus according to claim 1, further comprising a susceptor shaft supporting the susceptor plate, wherein a lower end of the susceptor shaft is connected to the reaction chamber.

3. The substrate processing apparatus according to claim 1, wherein the substrate lift mechanism further comprises:
a first lift shaft coupled to the lift pin support member;
a first shaft support member coupled to the first lift shaft;
a first bracket coupled to the first shaft support member;
a first ball screw rotatably coupled to the first bracket; and
a first motor coupled to the first ball screw and configured to rotate the first ball screw thereby moving the substrate in the vertical direction.

4. The substrate processing apparatus according to claim 1, wherein the gas supply unit further comprises:
a shower plate provided with a plurality of gas channels;
an upper body coupled to the shower plate;
a second lift shaft coupled to the upper body;
a second shaft support member coupled to the second lift shaft;
a second bracket coupled to the second shaft support member;
a second ball screw rotatably coupled to the second bracket; and
a second motor coupled to the second ball screw and configured to rotate the second ball screw thereby moving the shower plate in the vertical direction.

5. The substrate processing apparatus according to claim 1, further comprising a plurality of magnetic elements, one of which is provided to a lower end of each lift pin, and the other is provided to a surface of the lift pin support member.

6. The substrate processing apparatus according to claim 4, wherein the shower plate and susceptor plate serve as electrodes.

7. The substrate processing apparatus according to claim 6, further comprising an RF generator electrically coupled in RF power providing communication to the shower plate, with the susceptor plate electrically grounded.

8. The substrate processing apparatus according to claim 7, further comprising a first rod disposed between the RF generator and the shower plate and a second rod disposed between the susceptor plate and ground.

9. The substrate processing apparatus according to claim 4, wherein the susceptor assembly is provided with a heater.

10. The substrate processing apparatus according to claim 9, further comprising a third rod embedded within the susceptor shaft, the third rod being connected to the heater.

11. The substrate processing apparatus according to claim 10, wherein the third rod is power cable.

12. The substrate processing apparatus according to claim 11, wherein the third rod is provided with a plurality of cables, each of which is connected to a zone of the heater.

13. The substrate processing apparatus according to claim 10, wherein the third rod is thermocouple cable.

14. The substrate processing apparatus according to claim 7, wherein each of the second rod and the third rod is provided with a lower connector at lower end.

15. The substrate processing apparatus according to claim 14, further comprising upper connectors embedded in a bottom wall of the reaction chamber, wherein each of the upper connector is configured to connect the lower connector.

16. A substrate processing apparatus comprising:
one or more reaction chamber module, each reaction chamber module comprising two or more stations, each station comprising an upper compartment and a lower compartment, wherein the upper compartment is configured to contain a substrate during processing of the substrate, and wherein the lower compartment comprises a shared intermediate space between the two or more stations;
two or more susceptor assemblies, each of which are provided with a susceptor plate, being positioned in each station;
wherein the susceptor plate is constructed and arranged to support the substrate and provided with one or more holes formed therethrough;
wherein two or more substrate lift mechanisms are provided , each comprising:
a plurality of lift pins to support the substrate each station;
and a lift pin support member to move the lift pins;
wherein the substrate lift mechanism is configured to move in a vertical direction through the one or more holes;
a substrate transfer robot centrally disposed relative to the stations and provided with one or more robotic arms to transfer the substrate above the lift pins in the shared intermediate space; and
two or more gas supply units, each of which constructed and arranged to face the susceptor plate;
wherein the gas supply unit is configured to move in the vertical direction thereby positioning the substrate in a processing position of the upper compartment.

17. The substrate processing apparatus according to claim 16, wherein the susceptor assemblies further comprise a susceptor shaft supporting the susceptor plate, wherein a lower end of the susceptor shaft is connected to the reaction chamber.

18. The substrate processing apparatus according to claim 16, wherein the substrate transfer robot is configured to horizontally move the substrate from one of the stations to the other one of the stations.

19. The substrate processing apparatus according to claim 18, wherein the substrate transfer robot further comprise:
a shaft coupled to the robotic arms;
a motor rotatably coupled to the shaft to provide rotary movement to the robotic arms around an axis of the shaft.

20. The substrate processing apparatus according to claim 16, wherein each of the gas supply unit further comprises:
a shower plate provided with a plurality of gas channels;
an upper body coupled to the shower plate; and
a lift shaft coupled to the upper body.

21. The substrate processing apparatus according to claim 20, further comprising:
a common shaft support member coupled to the lift shafts;
a bracket coupled to the common shaft support member;
a ball screw rotatably coupled to the bracket; and
a motor coupled to the ball screw and configured to rotate the ball screw thereby moving the shower plate in the vertical direction.
